(19) United States
(12) Patent Application Publication
(10) Pub. No.: US 2026/0220343 A1
(43) Pub. Date: Jul. 30, 2026

(54) METHOD OF CONSTRUCTING AND METHOD OF SIMULATING EQUIVALENT CIRCUIT FOR CAPACITOR, AND SIMULATION DEVICE THEREFOR

(71) Applicant: TAIYO YUDEN CO., LTD., Tokyo (JP)

(72) Inventors: Shin ITAKURA, Tokyo (JP); Hiroyoshi KOBAYASHI, Tokyo (JP); Masayuki SHIMIZU, Tokyo (JP)

(73) Assignee: TAIYO YUDEN CO., LTD., Tokyo (JP)

(21) Appl. No.: 19/630,940

(22) Filed: Mar. 27, 2026

Related U.S. Application Data
(62) Division of application No. 15/718,934, filed on Sep. 28, 2017, now abandoned.

(30) Foreign Application Priority Data
Sep. 30, 2016 (JP) 2016-192611
Jun. 22, 2017 (JP) 2017-122149

(51) Int. Cl. G06F 30/367; H01G 4/30

(52) U.S. Cl. CPC G06F 30/367; H01G 4/30

(57) ABSTRACT

In a capacitor equivalent circuit model for when a DC voltage is superimposed on a signal, using an equivalent circuit for when the DC voltage is not applied as a baseline, a voltage-controlled current source or voltage source that adjusts the signal in accordance with the superimposed DC voltage is substituted with a portion that represents the capacitance of the equivalent circuit. The voltage-controlled current source or voltage source is then modeled using a current or voltage approximation formula that describes the change in the signal resulting from the changes in the characteristics of the capacitor due to superimposition of the DC voltage, and a device that represents the capacitance of the equivalent circuit behaves similar to a variable device due to superimposition of the DC voltage. This approximation formula reduces computational load on a simulator and prevents issues such as divergence.

### BACKGROUND OF THE INVENTION

### Technical Field

The present invention relates to a method of constructing and a method of simulating an equivalent circuit for a capacitor and to a simulation device therefor. More particularly, the present invention relates to a method of constructing and a method of simulating an equivalent circuit for a capacitor and to a simulation device therefor suitable for use when a DC voltage (a DC bias voltage) is superimposed onto a signal voltage.

### Background Art

Capacitors generally exhibit material- and structure-dependent frequency characteristics that differ from the characteristics of an ideal capacitive device. As a result, accurately calculating the performance of a capacitor using a simulator or the like requires an equivalent circuit model (typically provided by the capacitor manufacturer) that is matched against the measured frequency characteristics of the capacitor.

However, in recent years, particularly for multilayer ceramic capacitors, there has been increased need for models that model device performance when a DC voltage is superimposed, and simulation models that are only matched against frequency characteristics measured only when a signal is applied without a DC voltage cannot satisfy these needs.

Patent Document 1, for example, discloses a capacitor circuit simulation model, a method of constructing the same, a method of circuit simulation, and a circuit simulator as one solution to this problem. This solution provides an equivalent circuit model that, when a DC voltage is applied to the capacitor, automatically introduces a current corresponding to the characteristics of the applied DC voltage using a voltage-controlled current source. This makes it possible to reproduce the performance seen when a DC voltage is superimposed in actual measurements with a high degree of accuracy.

### RELATED ART DOCUMENT

### Patent Document

Patent Document 1: Japanese Patent Application Laid-Open Publication No. 2012-150579

### SUMMARY OF THE INVENTION

However, as illustrated in FIG. 1 of Patent Document 1 introduced above in the Background Art, the circuit configuration includes a differentiator element. Moreover, as illustrated in FIG. 6 of Patent Document 1, a large number of these differentiator elements are utilized, which can potentially cause issues such as divergence in results during actual measurements. Furthermore, the formula for approximating DC superimposition characteristics is a polynomial expression, which can also potentially cause divergence. In addition, the large number of complicated equations increases the computational load for software or the like used to perform the actual calculations and ultimately results in long computation times.

Moreover, due to the complexity of the equivalent circuit model configuration, constructing a simulation model for a single capacitor requires a massive amount of labor and man-hours. The simulation model can only be constructed by an individual with a high degree of technical ability, and finding individuals with these skills is difficult.

The present invention was made in light of the foregoing and aims to provide a method of constructing an equivalent circuit for a capacitor as well as a simulation method and a simulation device therefor that have a simple configuration, solve various problems in practical applicability arising from equivalent circuit model complexity, make it possible to satisfactorily approximate DC voltage superimposition characteristics, and have excellent practical applicability and usability. Accordingly, the present invention is directed to a scheme that substantially obviates one or more of the problems due to limitations and disadvantages of the related art.

Additional or separate features and advantages of the invention will be set forth in the descriptions that follow and in part will be apparent from the description, or may be learned by practice of the invention. The objectives and other advantages of the invention will be realized and attained by the structure particularly pointed out in the written description and claims thereof as well as the appended drawings.

To achieve these and other advantages and in accordance with the purpose of the present invention, as embodied and broadly described, in one aspect, the present disclosure provides a method of constructing an equivalent circuit for a capacitor to which a signal superimposed with a DC voltage may be applied, including: defining a reference equivalent circuit that represents characteristics of the capacitor when the DC voltage is not applied and only the signal is applied; determining a circuit value of each circuit element contained in the reference equivalent circuit by measuring responses of the capacitor when the DC voltage is not applied and only the signal is applied; substituting a circuit element or a group of circuit elements that are included in the reference equivalent circuit and that have circuit values that change when the DC voltage is superimposed to the signal with a voltage-controlled current source or voltage-controlled voltage source; and adding a closed circuit representing a state in which only the signal is applied to the voltage-controlled current source or voltage-controlled voltage source so that the voltage-controlled current source or voltage-controlled voltage source generates a current or voltage of a magnitude that is obtained by multiplying a current or voltage generated in the closed circuit by a coefficient.

One aspect of the present invention may further include: calculating a change in the circuit value of the circuit or the group of the circuit elements due to the superimposition of the DC voltage by comparing frequency characteristics of the circuit element or the group of circuit elements measured when the DC voltage is superimposed on the signal to frequency characteristics of the circuit elements or the group of circuit elements measured when only the signal is applied; and determining the coefficient on the basis of the change in the value of the circuit element or the group of circuit elements due to superimposition of the DC voltage as obtained in the step of calculating.

In another aspect of the present invention, in the closed circuit, a voltage source or current source may be connected in series to the circuit element or the group of circuit elements that have been substituted with the voltage-controlled current source or voltage-controlled voltage source, and an output of the voltage-controlled current source or voltage-controlled voltage source may be controlled in accordance with a voltage or current applied by the voltage source or current source to the closed circuit. Alternatively, the reference equivalent circuit may include a plurality of circuit elements that have same changes in response to the superimposition of the DC voltage, and a pair of the voltage-controlled current source or voltage-controlled voltage source and the associated closed circuit may be provided for the plurality of circuit elements. Moreover, the capacitor may be a multilayer ceramic capacitor.

In another aspect, the present disclosure provides a method of simulating characteristics of an electronic circuit that includes a capacitor, including: substituting the capacitor in the electronic circuit with an equivalent circuit for the capacitor constructed by the method of constructing according to the aforementioned aspect so as to construct an equivalent circuit for the electronic circuit; running a simulation program for the electronic circuit using the constructed equivalent circuit for the electronic circuit to output simulations results simulating the characteristics of the electronic circuit.

In another aspect, the present disclosure provides a simulation device for simulating characteristics of an electronic circuit that includes a capacitor, including: a processor programmed to receive an equivalent circuit for the electronic circuit, the equivalent circuit for the electronic circuit being constructed by substituting the capacitor in the electronic circuit with an equivalent circuit for the capacitor constructed by the method of constructing according to the aforementioned aspect, the processor running a simulation program for the electronic circuit using the constructed equivalent circuit for the electronic circuit and causing simulation results simulating the characteristics of the electronic circuit to be outputted.

In the present invention, using an equivalent circuit for when no DC voltage is applied as a baseline, a circuit representing changes in circuit characteristics due to superimposition of a DC voltage is added to a circuit device included in the equivalent circuit, thereby reducing computational load in simulations and also reducing the occurrence of computational problems due to divergence or the like. Moreover, the changes in the characteristics of passive components when the DC voltage is superimposed can be expressed in a relatively simple and highly accurate manner. It is to be understood that both the foregoing general description and the following detailed description are exemplary and explanatory, and are intended to provide further explanation of the invention as claimed.

### BRIEF DESCRIPTION OF THE DRAWINGS

FIGS. 1A and 1B are explanatory drawings illustrating a basic approach to representing a capacitive device according to Embodiment 1.

FIGS. 2A and 2B are explanatory drawings illustrating a basic approach to representing a resistive device according to Embodiment 1.

FIGS. 3A and 3B are explanatory drawings illustrating another basic approach to representing a capacitive device according to Embodiment 1.

FIGS. 4A and 4B are circuit diagrams illustrating examples of equivalent circuits for when no DC voltage is applied.

FIGS. 5A to 5C are graphs showing frequency characteristics when a DC voltage is not applied and when a DC voltage is superimposed.

FIGS. 6A and 6B are graphs showing the changes in the minimum capacitance value and the rate of change in capacitance of an equivalent circuit element when the superimposed DC voltage is changed.

FIGS. 7A and 7B are circuit diagrams illustrating a circuit configuration created by applying the equivalent circuits illustrated in FIGS. 1A and 1B & FIGS. 2A and 2B to the equivalent circuit portion illustrated in FIGS. 4A and 4B.

FIG. 8 is a circuit diagram illustrating an overall circuit configuration created by applying the equivalent circuits illustrated in FIGS. 1A and 1B & FIGS. 2A and 2B to the reference equivalent circuit illustrated in FIGS. 4A and 4B.

FIGS. 9A and 9B are explanatory drawings illustrating a basic approach according to Embodiment 2 of the present invention.

FIGS. 10A and 10B are explanatory drawings illustrating a method of grouping together a plurality of voltage-controlled voltage sources connected to the equivalent circuit in Embodiment 2.

FIG. 11 is a circuit diagram illustrating an equivalent circuit for when a DC voltage is superimposed in Embodiment 2.

FIG. 12 is a block diagram illustrating an embodiment of a simulation device according to the present invention.

### DETAILED DESCRIPTION OF EMBODIMENTS

Preferred embodiments of the present invention will be described in detail below.

### Embodiment 1

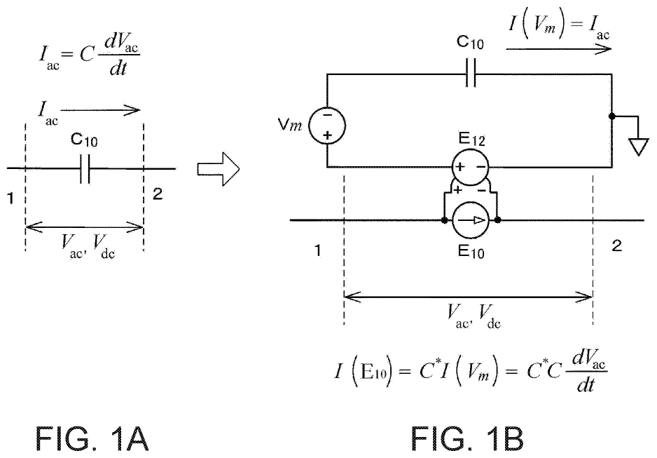

First, Embodiment 1 of the present invention will be described with reference to FIGS. 1A and 1B. As illustrated in FIG. 1A, when a signal voltage V_{ac} is applied across the terminals of a capacitive device C₁₀ of capacitance C, a signal current I_{ac} given by equation 1 flows.

$${I}_{ac} = C \frac{{d V}_{ac}}{dt} \qquad < Eq . 1 >$$

Meanwhile, as illustrated in FIG. 1B, the capacitive device C₁₀ in FIG. 1A is substituted with a voltage-controlled current source E₁₀, and the signal voltage V_{ac} is copied to a voltage source E₁₂. The capacitive device C₁₀ and a monitor voltage source Vₘ for monitoring current are connected in series to the voltage source E₁₂, thereby forming a closed circuit. Because the monitor voltage source Vₘ does not affect the current characteristics of this closed circuit, this closed circuit is equivalent to the circuit illustrated in FIG. 1A, and the signal current I_{ac} flowing through the capacitive device C₁₀ can be represented by equation 2.

$$I ( {V}_{m} ) = {I}_{ac} \qquad < Eq . 2 >$$

This signal current I_{ac} is monitored by the monitor voltage source Vₘ and fed back to the voltage-controlled current source E₁₀. The voltage-controlled current source E₁₀ multiplies the signal current I_{ac} by a coefficient C* and outputs the result. Thus, the current I(E₁₀) flowing between the terminals can be represented by equation 3. As shown by equation 3, the equivalent circuit illustrated in FIG. 1B is equivalent to a circuit connected to a capacitive device in which the capacitance C of the capacitive device C₁₀ is multiplied by C*. Therefore, using the voltage-controlled current source E₁₀ makes it possible to represent the characteristics of when a DC voltage is superimposed.

$$I ( {E}_{10} ) = {C}^{*} I ( {V}_{m} ) = {C}^{*} C \frac{{d V}_{ac}}{dt} \qquad < Eq . 3 >$$

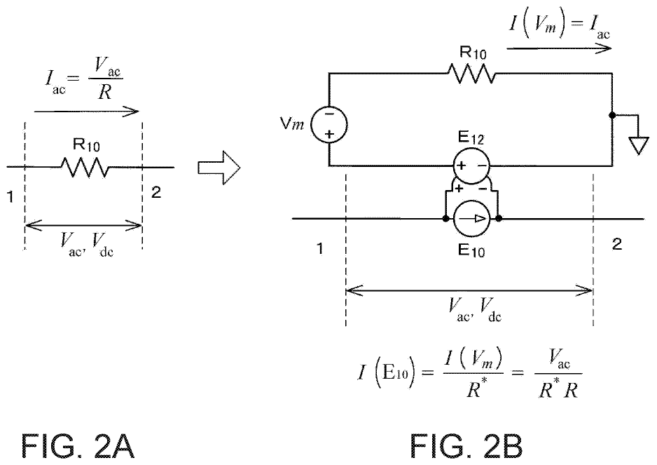

Using substantially the same procedure as for the capacitive device, an equivalent circuit for a resistive device in which the resistance is multiplied by R* can be obtained. In other words, as illustrated in FIG. 2A, when a signal voltage V_{ac} is applied across the terminals of a resistive device R₁₀ of resistance R, a signal current I_{ac} given by equation 4 flows.

$${I}_{ac} = \frac{{V}_{ac}}{R} \qquad < Eq . 4 >$$

Meanwhile, as illustrated in FIG. 2B, the resistive device R₁₀ in FIG. 2A is substituted with a voltage-controlled current source E₁₀, and the signal voltage V_{ac} is copied to a voltage source E₁₂. The resistive device R₁₀ and a monitor voltage source Vₘ for monitoring current are connected in series to the voltage source E₁₂, thereby forming a closed circuit. Because the monitor voltage source Vₘ does not affect the current characteristics of this closed circuit, this closed circuit is equivalent to the circuit illustrated in FIG. 2A, and the signal current I_{ac} flowing through the resistive device R₁₀ can be represented by equation 5.

$$I ( {V}_{m} ) = {I}_{ac} \qquad < Eq . 5 >$$

This signal current I_{ac} is monitored by the monitor voltage source Vₘ and fed back to the voltage-controlled current source E₁₀. The voltage-controlled current source E₁₀ multiplies (divides) the signal current I_{ac} by a coefficient R* and outputs the result. Thus, the current I(E₁₀) flowing between the terminals can be represented by equation 6. As shown by equation 6, the equivalent circuit illustrated in FIG. 2B is equivalent to a circuit connected to a resistive device in which the resistance R of the resistive device R₁₀ is multiplied by R* (and the current is multiplied by 1/R*).

$$I ( {E}_{10} ) = \frac{I ( {V}_{m} )}{{R}^{*}} = \frac{{V}_{ac}}{{R}^{*} R} \qquad < Eq . 6 >$$

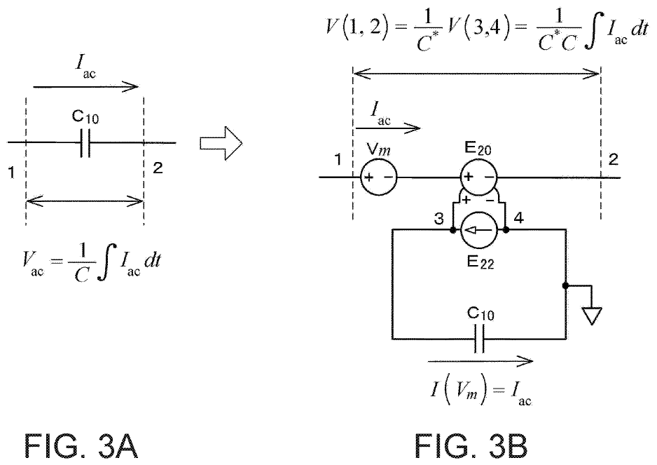

Furthermore, it is also possible to configure an equivalent circuit in which the capacitance of a capacitive device C₁₀ is multiplied by C* using a voltage-controlled voltage source. As illustrated in FIG. 3A, the signal voltage V_{ac} across the terminals of the capacitive device C₁₀ of capacitance C can be expressed in terms of the signal current I_{ac} by equation 7.

$${V}_{ac} = \frac{1}{C} \int {I}_{ac} dt \qquad < Eq . 7 >$$

Meanwhile, as illustrated in FIG. 3B, the capacitive device C₁₀ in FIG. 3A is substituted with a voltage-controlled voltage source E₂₀, and a monitor power source Vₘ is connected in series thereto. The signal current Lac monitored by this monitor power source Vₘ is copied to a current source E₂₂. The capacitive device C₁₀ is connected in series to the current source E₂₂, thereby forming a closed circuit. This closed circuit is equivalent to the circuit illustrated in FIG. 3A, and the signal current I_{ac} flowing through the capacitive device C₁₀ can be represented by equation 8.

$$I ( {V}_{m} ) = {I}_{ac} \qquad < Eq . 8 >$$

Moreover, when the signal voltage V_{ac} applied to the capacitive device C₁₀ is fed back to the voltage-controlled voltage source E₂₀ and the voltage-controlled voltage source E₂₀ multiplies this feedback voltage by 1/C* and outputs the result, the monitor voltage source Vₘ does not affect the circuit characteristics, and therefore the terminal voltage V(1,2) can be represented by equation 9, where V(3,4) is the terminal voltage of the current source E₂₂. This ultimately yields an equivalent circuit in which the capacitance C of the capacitive device C₁₀ is multiplied by C*.

$$V ( 1 , 2 ) = \frac{1}{{C}^{*}} V ( 3 , 4 ) = \frac{1}{{C}^{*} C} \int {I}_{ac} dt \qquad < Eq . 9 >$$

Using the same procedure for a resistive device, the output of a voltage-controlled voltage source can be multiplied by R* to obtain an equivalent circuit in which the resistance of the resistive device is multiplied by R*.

Thus, by determining, by way of measurement, for capacitive elements and resistive elements in an equivalent circuit for a capacitor built for when a DC voltage V_{dc} is not applied (not superimposed) and only a signal voltage V_{ac} is applied (hereinafter, a “reference equivalent circuit”), the percentage change in capacitance and the percentage change in resistance, respectively, when the DC voltage V_{dc} is superimposed, and then connecting a voltage-controlled current source (or a voltage-controlled voltage source as in FIG. 3B) in each of the elements in accordance with the respective changes in capacitance/resistance as described above, the DC voltage dependent characteristics of a capacitor can be adequately represented. In other words, an equivalent circuit for when the DC voltage V_{ac} is superimposed on the signal voltage V_{ac} can be obtained by doing the following.
(a) Determine, by measuring in advance, the circuit constants of capacitive elements and resistive elements included in the reference equivalent circuit.
(b) Determine, by measuring, the values of the capacitive elements and resistive elements when the DC voltage V_{ac} is applied and superimposed onto the signal voltage V_{ac}.
(c) For each of the elements, use the values of the element when the DC voltage V_{dc} was 0 determined in step (a) and the values of the element when the DC voltage was superimposed (V_{ac}+V_{dc}) determined in step (b) to calculate the percentage change in capacitance/resistance due to the DC voltage being superimposed.
(d) Using the calculated percentage changes, calculate the current I(E₁₀) with equation 3 or 6 for each of the elements.
(e) Connect a voltage-controlled current source E₁₀ (or the voltage-controlled voltage source E₂₀ as in FIG. 3B) having the calculated current I(E₁₀) in place of each capacitive/resistive element in the reference equivalent circuit.

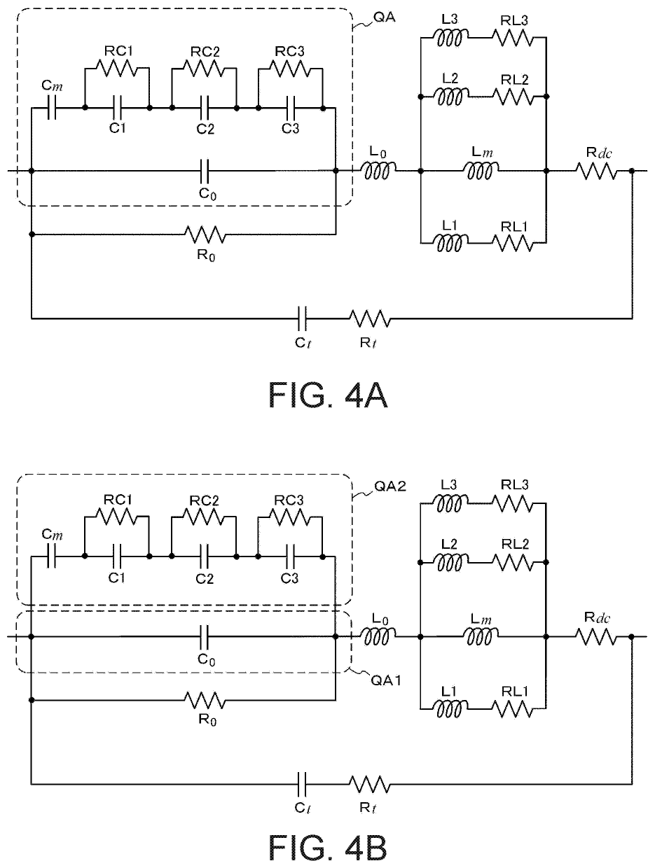

FIG. 4A illustrates an example of a reference equivalent circuit in which no DC voltage V_{dc} is applied. This reference equivalent circuit is a well-known configuration taken from FIG. 17 of Japanese Patent Application Laid-Open Publication No. 2013-228997. As illustrated in FIG. 4A, capacitors Cₘ and C1 to C3 are connected in series, and resistors RC1 to RC3 are respectively connected in parallel to the capacitors C1 to C3. Moreover, a capacitor C₀ is connected in parallel to this overall circuit. This equivalent circuit portion QA is a capacitive portion, and substituting each of the elements included in this portion with a voltage-controlled current source reflecting a percentage change due to superimposition of a DC voltage makes this portion an equivalent circuit for the DC voltage superimposition characteristics.

Furthermore, a resistor R₀ and an inductor L₀ are connected in parallel and series, respectively, to the equivalent circuit portion QA. Moreover, an inductor Lₘ is connected in parallel to three series circuits in which inductors L1 to L3 are respectively connected in series to resistors RL1 to RL3, and this overall circuit is connected in series to the inductor L₀. A resistor R_{dc} is also connected in series. In addition, a series circuit constituted by a capacitor Ct and a resistor Rₜ is connected in parallel to the overall circuit described above.

The equivalent circuit portion QA described above includes eight circuit devices, and although the percentage change in capacitance or the percentage change in resistance for when a DC voltage is superimposed may be obtained for each device individually, this would not necessarily be an efficient approach. Therefore, in the present embodiment, the frequency characteristics of several multilayer ceramic capacitor samples are used.

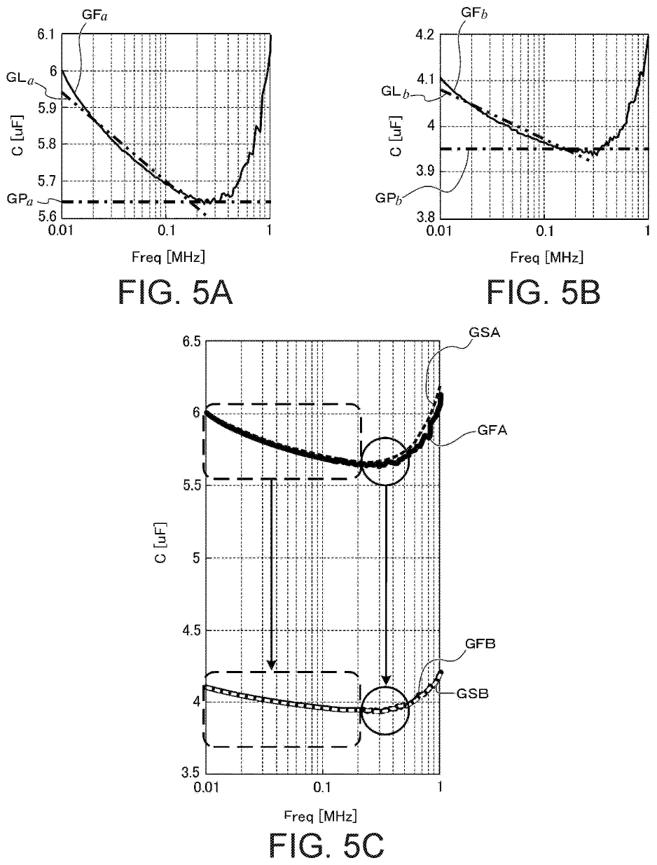

FIGS. 5A to 5C show the frequency characteristics of multilayer ceramic capacitor samples made of a typical material when a low amplitude signal was applied. Here, the frequency characteristics for when a low amplitude signal was applied were measured using several types of 22 μF multilayer ceramic capacitor samples made by the applicant, for example. FIG. 5A shows the characteristics when no DC voltage was applied, and FIG. 5B shows the characteristics when a DC voltage was superimposed. In the graphs, the horizontal axis represents frequency (on a logarithmic scale) and the vertical axis represents capacitance.

As shown by the solid lines GFₐ and GF_{b}, the capacitance of the capacitors decreases linearly relative to the logarithm of frequency before ultimately reaching a minimum capacitance value and converging at that value. The dashed lines GLₐ and GL_{b} are linear lines illustrating the decrease in capacitance, and GPₐ and GP_{b} are the minimum values. Comparing these graphs makes it clear that the slope of the lines GLₐ and GL_{b} as well as the minimum values GPₐ and GP_{b} change between when the DC voltage V_{dc} is not applied and when the DC voltage V_{dc} is superimposed. Therefore, in multilayer ceramic capacitors, the changes in capacitance frequency characteristics resulting from whether a DC voltage is superimposed are characterized by changes in two parameters: the rates of change in capacitance ΔGLₐ and ΔGL_{b} given by the slopes of the lines GLₐ and GL_{b}, and the minimum capacitance values GPₐ and GP_{b}.

Thus, an equivalent circuit for when the DC voltage V_{dc} is superimposed should simply include elements corresponding to the rates of change in capacitance ΔGLₐ and ΔGL_{b} and the minimum capacitance values GPₐ and GP_{b}, and the percentage changes in capacitance and resistance due to superimposition of a DC voltage V_{ac} do not necessarily need to be individually obtained for all eight circuit elements included in the equivalent circuit portion QA illustrated in FIG. 4A. In practice, the capacitance frequency characteristics of a multilayer ceramic capacitor for when a DC voltage is not applied are mapped to a reference equivalent circuit, and the circuit constants thereof are set as reference values. Then, when the DC voltage is superimposed, common percentage changes due to the applied voltage can be respectively multiplied with the constants of each element in the equivalent circuit portions QA1 and QA2, respectively, which are illustrated in FIG. 4B, in order to determine the equivalent circuit constants for when the DC voltage is superimposed.

FIG. 5C illustrates this approach. In FIG. 5C, the solid line GFA shows the capacitance frequency characteristics of a 22 μF multilayer ceramic capacitor made by the applicant as measured when no DC voltage was applied, and the solid line GFB shows the capacitance frequency characteristics of the same capacitor as measured when a DC voltage was superimposed. Here, the superimposed DC voltage V_{ac} is 1V. As illustrated by these curves, superimposing the DC voltage V_{dc} decreases the rate of change in capacitance and the minimum capacitance value, and the curve GFA becomes the curve GFB.

Meanwhile, the dashed line GSA shows the result of mapping the capacitance frequency characteristics measured when no DC voltage was applied to the reference equivalent circuit illustrated in FIG. 4B. Specific examples of values for each circuit device are as follows.

$${C}_{m} = 1.5718 μF$$

$$C 1 = 1 μF$$

$$C 2 = 0.5 \; 2638 μF$$

$$C 3 = 0.0 \; 01 μF$$

$$RC 1 = 3 6.345 Ω$$

$$RC 2 = 7.9 \; 335 Ω$$

$$RC 3 = 6.5 \; 488 Ω$$

Taking these circuit constants for when the DC voltage is not applied, the capacitance of the capacitor C₀ in the equivalent circuit portion QA1 is multiplied by approximately 0.698, the capacitances of the capacitors Cₘ and C1 to C3 in the equivalent circuit portion QA2 are multiplied by approximately 0.48, and the resistances of the resistors RC1 to RC3 are multiplied by approximately 1/0.48 to create an equivalent circuit. Graphing the capacitance frequency characteristics of this equivalent circuit yields the dashed curve GSB. This curve matches the curve GFB for the measured values extremely closely. Moreover, changing the capacitance of the capacitor C₀ in the equivalent circuit portion QA1 mainly changes the minimum capacitance value of the curve GSB (corresponding to GPₐ and GP_{b}), and changing the capacitances of the capacitors Cₘ and C1 to C3 or the resistances of the resistors RC1 to RC3 in the equivalent circuit portion QA2 mainly changes the rate of change in capacitance of the curve GSB (corresponding to the slopes of the curves GLₐ and GL_{b}). In this way, the characteristics of the equivalent circuit portion QA1 of the reference equivalent circuit illustrated in FIG. 4B substantially correspond to the minimum capacitance value of the capacitor portion QA being simulated, and the characteristics of the equivalent circuit portion QA2 substantially correspond to the rate of change in capacitance in the capacitor portion QA being simulated.

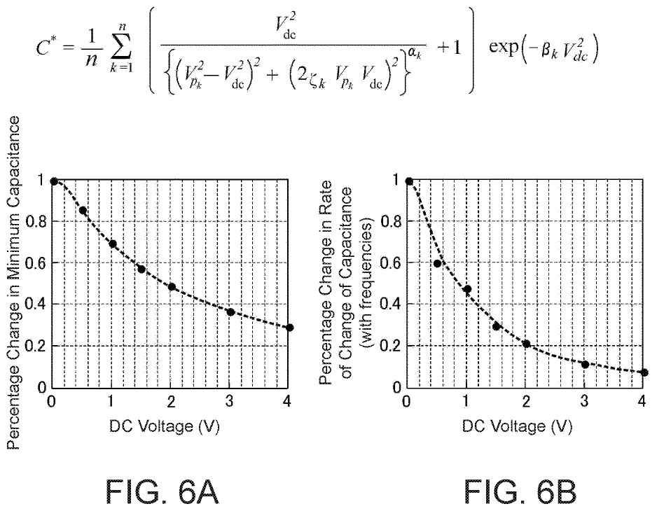

Although FIGS. 5A to 5C illustrate a case in which a DC voltage V_{ac} of 1V is superimposed, repeating the same process for different values of the DC voltage V_{dc} makes it possible to obtain the relationship between the DC voltage V_{dc} and the percentage change in the circuit constants of the elements included in the equivalent circuit portions QA1 and QA2. In FIG. 6A, the circles represent values calculated on the basis of measured values of the minimum capacitance value as a function of the DC voltage V_{ac}, and in FIG. 6B, the circles represent values calculated on the basis of measured values of the rate of change in capacitance as a function of the DC voltage V_{dc}. FIG. 6A corresponds to the percentage change (that is, the percentage change relative to the value when no DC voltage is applied) of the capacitor C₀ of the equivalent circuit portion QA1, and FIG. 6B corresponds to the percentage change (that is, the percentage change relative to the value when no DC voltage is applied) in the capacitances of the capacitors Cₘ and C1 to C3 as well as to the reciprocal of the percentage change in the resistances of the resistors RC1 to RC3 in the equivalent circuit portion QA2 that substantially determines the rate of change in capacitance with frequencies in the capacitor portion QA being simulated, as described above.

Representing the measured value curves in FIGS. 6A and 6B mathematically yields equation 10. Here, Vₚₖ, ζₖ, αₖ, and βₖ are fitting coefficients.

$${C}^{*} = \frac{1}{n} {\sum }_{k = 1}^{n} ( \frac{{V}_{dc}^{2}}{{\{ {( {V}_{Pk}^{2} - {V}_{dc}^{2} )}^{2} + {( {2}_{ζk} {V}_{Pk} {V}_{dc} )}^{2} \}}^{{α}_{k}}} + 1 ) exp ( - {β}_{k} {V}_{dc}^{2} ) \qquad < Eq . 10 >$$

As shown by equation 10, this function is an even function relative to the DC voltage V_{dc}, is symmetric to reverse voltages, and exhibits no potential for divergence of the type seen in power series. Therefore, conflicts in calculation results and high computation loads are not likely to occur on a simulator. Thus, by substituting each of the equivalent circuit portions QA1 and QA2 with a voltage-controlled current source that uses equation 10 to characterize the percentage change in the respective circuit constant due to superimposition of a DC voltage, it becomes possible to express the percentage change in capacitance and the percentage change in resistance due to the DC voltage V_{dc} being superimposed.

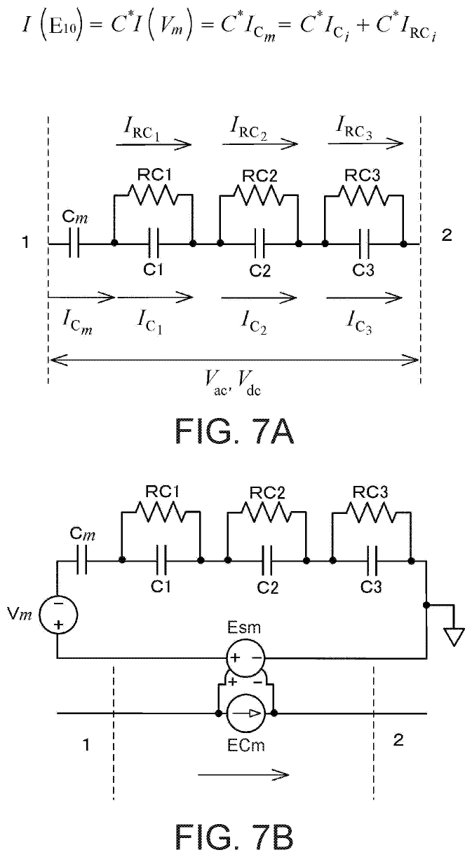

Next, an example of applying the equivalent circuits illustrated in FIGS. 1A and 1B & FIGS. 2A and 2B to the equivalent circuit portion QA described above and illustrated in FIG. 4A will be described. Consider the equivalent circuit portion QA2 illustrated in FIGS. 4B and 7A, for example, where each device is respectively substituted by the equivalent circuits illustrated in FIGS. 1B and 2B, and in which the capacitances of the capacitors Cₘ and C1 to C3 are multiplied by C* and the resistances of the resistors RC1 to RC3 are multiplied by 1/C*. With respect to the capacitor C1 and the resistor RC1 that are connected in parallel, a voltage-controlled current source representing the respective percentage change should be connected to each of the elements, as described above. But here, these current sources are consolidated. The voltage-controlled current sources for the group of the capacitor C2 and the resistor RC2 as well as for the group of the capacitor C₃ and the resistor RC3 are similarly respectively consolidated together, and furthermore, the overall equivalent circuit portion QA2 is actually provided with a single voltage-controlled current source EC₀.

Similar to in the single-device case, when the feedback current is multiplied by C*, Kirchoff's laws can be used to obtain equation 11 below. In equation 11, I_{Ci} is the currents I_{Cm}, I_{C1}, I_{C2}, and I_{C3} of the capacitors Cₘ, C1, C2, and C3, and I_{RCi}, is the currents I_{RC1}, I_{RC2}, and I_{RC3} of the resistors RC1, RC2, and RC3. Here, the voltage applied to the elements Cₘ, C1 to C3, and RC1 to RC3 does not change, and therefore the current flowing through each of the elements in the equivalent circuit portion QA2 is effectively multiplied by C*. Therefore, the equivalent circuit in FIG. 7B is equivalent to a circuit in which the capacitances of the capacitors Cₘ and C1 to C3 are multiplied by C* and the resistances of the resistors RC1 to RC3 are multiplied by 1/C* in the equivalent circuit portion QA2 in FIG. 7A. Thus, it is not necessary to construct an equivalent circuit using separate current sources for each device, and it is possible to obtain an equivalent circuit having a simple configuration in which the individual current sources are grouped together.

$$I ( {E}_{{C}_{m}} ) = {C}^{*} ( {V}_{{C}_{m}} ) = {C}^{*} {I}_{{C}_{m}} = {C}^{*} {I}_{{C}_{i}} + {C}^{*} {I}_{{RC}_{i}} \qquad < Eq . 11 >$$

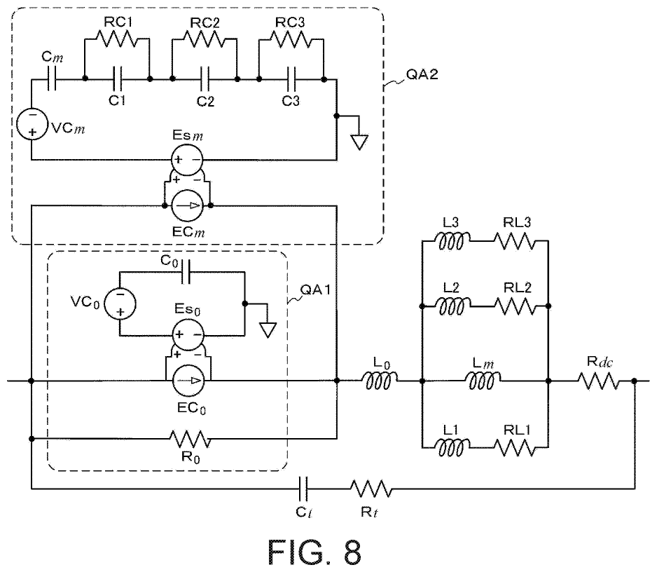

Similarly, by applying the equivalent circuit in FIG. 1B to the equivalent circuit portion QA1, the equivalent circuit in FIG. 4B becomes the circuit illustrated in FIG. 8.

Next, the overall approach of the present embodiment will be described.
(a) The circuit constants of the circuit elements included in the reference equivalent circuit in FIG. 4B are respectively determined on the basis of frequency characteristic measurements made in a state in which the DC voltage V_{ac} is not superimposed on the capacitor QA to be simulated.
(b) Next, the frequency characteristics are measured when the DC voltage V_{dc} is superimposed to obtain the graphs illustrated in FIGS. 6A and 6B.
(c) Then, these graphs are used to determine parameters of equation 10 that represents the coefficients C* and R* for the voltage-controlled current sources EC₀ and ECₘ in FIG. 8.
(d) As a result, when the DC voltage V_{ac} is superimposed, the circuit shown in FIG. 8 generates appropriate changes in the circuit constants in response to the superimposition of the DC voltage V_{ac}, owing to the outputs of the currents I(EC₀) and I(ECₘ) from the voltage-controlled current sources EC₀ and ECₘ.
(e) The equivalent circuit illustrated in FIG. 8 is formulated in a SPICE model format compatible with a typical SPICE simulator (such as LTspice or PSpice), and this SPICE model is used to run simulations on the simulator. Alternatively, the circuit constant for each element in the equivalent circuit as well as data describing the percentage changes in constants of elements in the capacitive portion may be input to a standalone or web-based software application, and the calculations presented in the embodiment as described above may be performed in the software application to present graphs and data characterizing the frequency characteristics of the target multilayer ceramic capacitor when arbitrary DC voltages are applied, to search for capacitors that satisfy specified frequency characteristics when arbitrary DC voltages are applied, to calculate frequency characteristics in case of simpler equivalent circuits, and the like.

In the present embodiment as described above, using the equivalent circuit for when no DC voltage is applied illustrated in FIG. 4A as a baseline, the voltage-controlled current sources EC₀ and ECₘ that adjust the signal current I_{ac} in accordance with the superimposed DC voltage V_{ac} are connected in parallel in the portion QA that represents the capacitance of that equivalent circuit, so that the voltage-controlled current sources EC₀ and ECₘ produce appropriate changes in the signal current due to the changes in characteristics of the capacitor under the DC voltage bias. Thus, the element that represents the capacitance of the reference equivalent circuit behaves as a variable capacitor when the DC voltage is superimposed. The approximation formula (equation 10) for the coefficients (C* and R*) used in the currents of the voltage-controlled current sources EC₀ and ECₘ (equations 3 and 6) in this embodiment reduces computational load during simulation and does not exhibit computational problems due to divergence or the like in the range of the voltages to be used. This makes it possible to quickly and accurately represent, in the form of an equivalent circuit, the characteristics of a multilayer ceramic capacitor when an arbitrary DC voltage is superimposed. Moreover, the equivalent circuit has a relatively simple configuration, thereby making tasks such as matching against measurements easier during creation of the equivalent circuit as well as improving the ease and efficiency of equivalent circuit creation.

### Embodiment 2

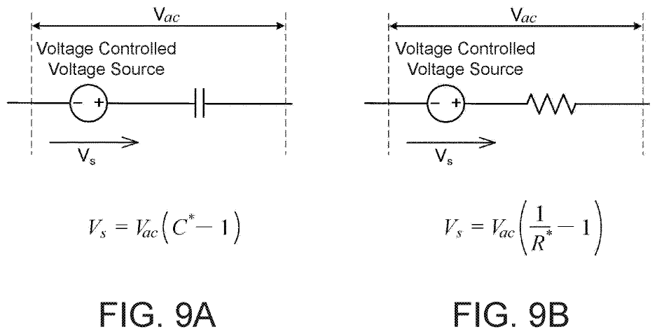

Next, Embodiment 2 of the present invention will be described with reference to FIGS. 9A and 9B to 11. As illustrated in FIG. 9A, when a voltage-controlled voltage source is connected in series to a capacitive element and the voltage-controlled voltage source applies a voltage Vₛ given by equation 12, the capacitance of the capacitive element appears to change by an amount of change in C*.

$${V}_{s} = {V}_{ac} ( {C}^{*} - 1 ) \qquad < Eq . 12 >$$

Similarly, as illustrated in FIG. 9B, when a voltage-controlled voltage source is connected in series to a resistive element and the voltage-controlled voltage source applies a voltage Vₛ given by equation 13, the resistance of the resistive element appears to change by an amount of change in R*.

$${V}_{s} = {V}_{ac} ( \frac{1}{{R}^{*}} - 1 ) \qquad < Eq . 13 >$$

Thus, by determining, by way of measurement, for capacitive elements and resistive elements in a reference equivalent circuit that is built for when a DC voltage V_{dc} is not applied (not superimposed) and only a signal voltage V_{ac} is applied, the percentage change in capacitance and the percentage change in resistance when the DC voltage V_{ac} is superimposed, and then connecting a voltage-controlled voltage source in series to each element, as described above, the DC voltage dependent characteristics of a capacitor represented by the reference equivalent circuit can be adequately represented. In other words, an equivalent circuit for when the DC voltage V_{dc} is superimposed on the signal voltage V_{ac} can be obtained by doing the following.
(a) Determine, by measuring in advance, the circuit constants of capacitive elements and resistive elements included in the reference equivalent circuit.
(b) Determine, by measuring, the values of the capacitive elements and resistive elements when the DC voltage V_{dc} is applied and superimposed onto the signal voltage V_{ac}.
(c) For each of the elements, use the values of the element from when the DC voltage V_{dc} was 0 determined in step (a) and the values of the element from when the DC voltage was superimposed (V_{ac}+V_{dc}) determined in step (b) to calculate the percentage change in capacitance and the percentage change in resistance due to the DC voltage being superimposed.
(d) Using the calculated percentage changes, calculate the voltage Vₛ with equation 12 or 13 for each of the elements.
(e) Connect a voltage-controlled voltage source having the calculated voltage Vₛ in series to each of the capacitive/resistive device in the reference equivalent circuit.

Next, the connection of a voltage-controlled voltage source to the reference equivalent circuit illustrated in FIG. 4B will be described. First, in the equivalent circuit portion QA1, a voltage-controlled voltage source DE1 having a voltage calculated by applying the percentage change given in the graph in FIG. 6A to equation 12 is connected to the capacitor C₀. Next, consider the equivalent circuit portion QA2. Here, the capacitors C1 to C3 are respectively connected in parallel to the resistors RC1 to RC3, forming three groups. The percentage change in capacitance is the same for each device in the equivalent circuit portion QA2, and the percentage change in resistance is the reciprocal of the percentage change in capacitance (see equation 13). Therefore, connecting a voltage-controlled voltage source having a percentage change given by equation 10 to each parallel-connected device yields an admittance Y given by equation 14. In equation 14, C is the capacitance of the parallel-connected capacitor, and R is the resistance of the parallel-connected resistor.

$$Y = j {ωC}^{*} C + \frac{\frac{1}{R}}{{C}^{*}} = {C}^{*} ( j ωC + \frac{1}{R} ) \qquad < Eq . 14 >$$

As shown in equation 14, this admittance Y is the same as the admittance Y of a circuit in which a voltage-controlled voltage source having the abovementioned percentage change in capacitance is connected to the overall group of the parallel-connected capacitor and resistor. Therefore, the voltage-controlled voltage sources for each group of parallel-connected devices can be grouped together into a single voltage-controlled voltage source.

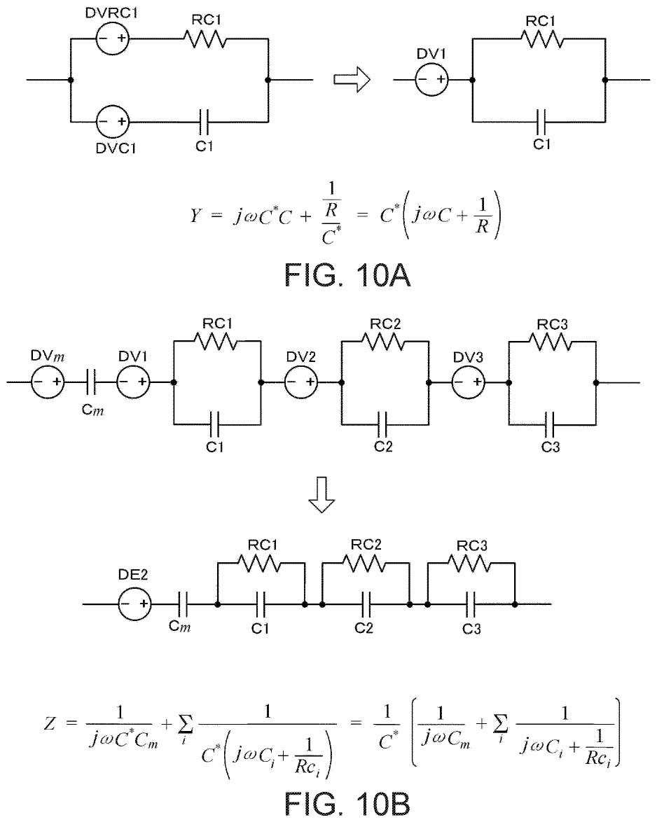

FIG. 10A illustrates this approach. With respect to the capacitor C1 and the resistor RC1 that are connected in parallel, voltage-controlled voltage sources DVC1 and DVRC1 respectively representing their percentage changes should be connected to the capacitor C1 and the resistor RC1, respectively, as described above. But here, these voltage sources are grouped together as a voltage-controlled voltage source DV1. This also applies to the group of the capacitor C2 and the resistor RC2 and to the group of the capacitor C3 and the resistor RC3.

Thus, the voltage-controlled voltage sources for the equivalent circuit portion QA2 can be represented as illustrated by DVₘ and DV1 to DV3 in FIG. 10B, and the resulting circuit has four impedances having the same percentage change in capacitance connected together in series. Equation 15 gives the overall impedance for these series-connected voltage-controlled voltage sources DVₘ and DV1 to DV3 having the same percentage change. Therefore, as illustrated in FIG. 10B, this circuit is equivalent to connecting together all of the elements other than the voltage-controlled voltage sources and then connecting a single voltage-controlled voltage source DE2 in series.

$$Z = \frac{1}{j ω {C}^{*} {C}_{m}} + {\sum }_{i} \frac{1}{{C}^{*} ( j ω {C}_{i} + \frac{1}{{R c}_{i}} )} = \frac{1}{{C}^{*}} ( \frac{1}{j ω {C}_{m}} + {\sum }_{i} \frac{1}{j ω {C}_{i} + \frac{1}{{R c}_{i}}} ) \qquad < Eq . 15 >$$

Next, the additional superimposed DC voltage V_{dc} must be removed for when the voltage-controlled voltage sources DE1 and DE2 detect the signal voltage V_{ac}. Therefore, the input voltage to the reference equivalent circuit (signal voltage V_{ac}+superimposed DC voltage V_{dc}) is passed through a high-pass filter with an extremely low cutoff frequency in order to remove the DC component and is then supplied to the voltage-controlled voltage sources DE1 and DE2 as a detection signal. Adding such a filter circuit along with the voltage-controlled voltage sources DE1 and DE2 to the reference equivalent circuit illustrated in FIG. 4B makes it possible to obtain an equivalent circuit that represents the frequency characteristics of when the DC voltage V_{dc} is superimposed.

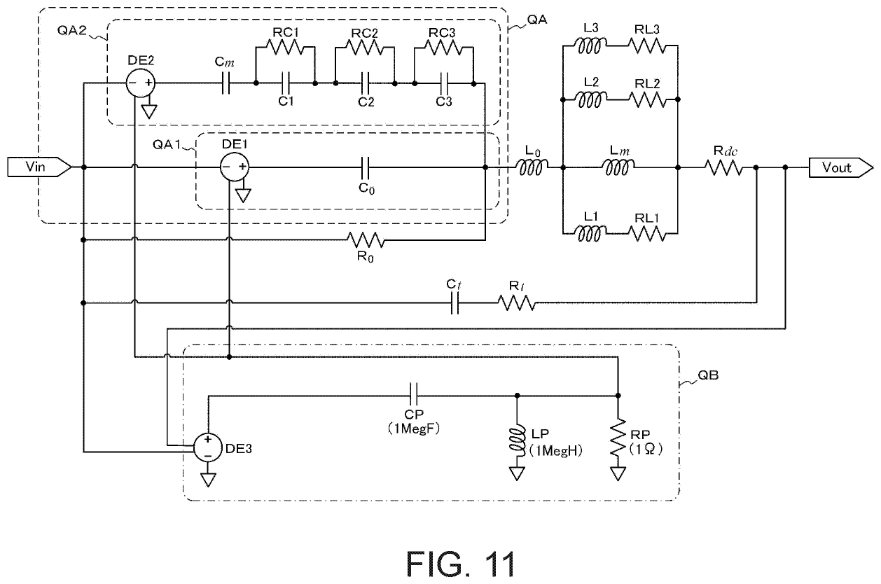

FIG. 11 illustrates an example of such an equivalent circuit. The voltage-controlled voltage source DE1 is connected in series in the equivalent circuit portion QA1, and the voltage-controlled voltage source DE2 is connected in series in the equivalent circuit portion QA2. Moreover, a filter circuit QB includes a high-pass filter constituted by a series capacitor CP and a parallel inductor LP and is configured to detect the signal voltage V_{ac} via a load RP. Furthermore, a voltage-controlled voltage source DE3 is respectively connected to the input side and the output side of the equivalent circuit and thus receives an input voltage Vin and an output voltage Vout. The voltage-controlled voltage source DE3 outputs the difference between the input voltage Vin and the output voltage Vout. In addition, the additional DC voltage V_{dc} is removed from that difference by the high-pass filter, and the signal voltage V_{ac} is detected by the load RP and then respectively supplied to the voltage-controlled voltage sources DE1 and DE2.

Next, the overall operations of the present embodiment will be described. (a) The circuit constants of the circuit devices included in the reference equivalent circuit in FIG. 4B are respectively determined on the basis of frequency characteristic measurements made in a state in which the DC voltage V_{dc} is not superimposed on the capacitor to be simulated. (b) Next, the frequency characteristics are measured when the DC voltage V_{dc} is superimposed to obtain the graphs illustrated in FIGS. 6A and 6B. (c) Then, these graphs are used to determine parameters of equation 10 to derive the coefficient C* for the voltage-controlled voltage sources DE1 and DE2 in FIG. 11. Note that in this example, equation 15 guarantees that the coefficients can be grouped for the voltage-controlled voltage source DE2. However, if the coefficients need to be determined individually (C*≠1/R*), then the voltage sources cannot be grouped together as with the voltage-controlled voltage source DE2, and therefore a separate voltage-controlled voltage source is left connected in series to each individual element. (d) As a result, when the DC voltage V_{dc} is superimposed, the signal voltage V_{ac} is detected with the filter circuit QB illustrated in FIG. 11, and the circuit shown in FIG. 11 generates appropriate changes in the circuit constants in response to the superimposition of the DC voltage V_{dc}, owing to the outputs of voltages Vₛ from the voltage-controlled voltage sources DE1 and DE2. (e) The equivalent circuit illustrated in FIG. 11 is formulated in a SPICE model format compatible with a typical SPICE simulator (such as LTspice or PSpice), and this SPICE model is used to run simulations on the simulator. Alternatively, the circuit constant for each element in the equivalent circuit as well as data describing the percentage changes in constants of elements in the capacitive portion may be input to a standalone or web-based software application, and the calculations presented in the embodiment as described above may be performed in the software application to present graphs and data characterizing the frequency characteristics of the target multilayer ceramic capacitor when arbitrary DC voltages are applied, to search for capacitors that satisfy specified frequency characteristics when arbitrary DC voltages are applied, to calculate frequency characteristics in case of simpler equivalent circuits, and the like.

In the present embodiment as described above, using the equivalent circuit for when no DC voltage is applied illustrated in FIG. 4A as a baseline, the voltage-controlled voltage sources DE1 and DE2 that adjust the signal voltage V_{ac} in accordance with the superimposed DC voltage V_{ac} are connected in series in the capacitive portion QA that represents the capacitance of that equivalent circuit, so that the voltage-controlled voltage sources DE1 and DE2 produce appropriate changes in the signal voltage due to the changes in the characteristics of the capacitor when the DC voltage is superimposed. Thus, the element that represents the capacitance of the reference equivalent circuit behaves as a variable capacitor when the DC voltage is superimposed. The approximation formula (equation 10) for the coefficients (C* and R*) used in the voltages of the voltage-controlled voltage sources DE1 and DE2 (equations 12 and 13) in this embodiment reduces computational load during simulation and does not exhibit computational problems due to divergence or the like resulting from the voltages used. This makes it possible to quickly and accurately represent, in the form an equivalent circuit, the characteristics of a multilayer ceramic capacitor when an arbitrary DC voltage is superimposed. Moreover, the equivalent circuit has a relatively simple configuration, thereby making tasks such as matching against measurements easier during creation of the equivalent circuit as well as improving the ease and efficiency of equivalent circuit creation.

### Embodiment 3

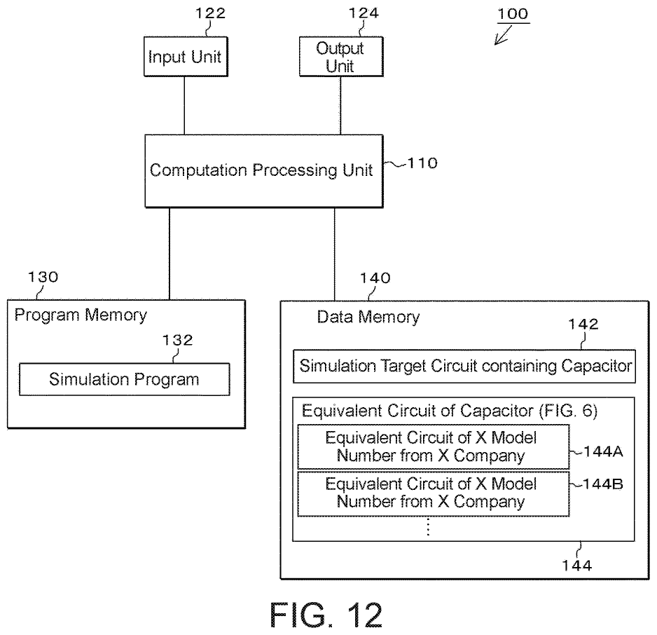

Next, an embodiment of a simulation device will be described with reference to FIG. 12. A simulation device 100 according to the present embodiment is a general-purpose computer system in which an input unit 122 such as a keyboard, an output unit 124 such as a liquid crystal display, a program memory 130, and a data memory 140 are connected to a CPU-based processor 110. The program memory 130 stores a simulation program 132 (such as a SPICE simulator). The data memory 140 stores simulation target circuits 142 including capacitors as well as capacitor equivalent circuits 144 of the types illustrated in FIGS. 8 to 11.

The simulation target circuits 142 are circuits in which a DC voltage V_{dc} is superimposed on a signal voltage V_{ac}, such as in power supply lines for computation processing ICs such as CPUs, for example. The capacitor equivalent circuits 144 are respectively prepared for respective capacitors. For example, equivalent circuits 144A, 144B, and so on are prepared for manufacturer XYZ's model ABC capacitor, and so on. Moreover, when the simulation program 132 is a SPICE simulator, the capacitor equivalent circuits 144 are provided as SPICE files.

Upon receiving an instruction specifying the manufacturer and model of a capacitor to use for a capacitor included in one of the simulation target circuits 142, the equivalent circuit 144 for the corresponding capacitor is loaded from the data memory 140 and connected at the position of the respective capacitor in the simulation target circuit 142. Then, the processor 110 runs the simulation program 132 stored in the program memory 130 on that circuit to perform the desired simulation. Using the equivalent circuits for when a DC voltage is superimposed illustrated in FIGS. 8 to 11 makes it possible to reduce simulation time and to efficiently run high-accuracy simulations.

The present embodiment as described above exhibits the following advantageous effects.
(1) Electronic component manufacturers and distributors can provide equivalent circuits for when DC voltages are superimposed on their capacitors to customers or publish these equivalent circuits on the company website, thereby making it possible to increase the ease of circuit design for customers using those products and also making it possible to create product sales opportunities.
(2) By using the published equivalent circuits for when DC voltages are superimposed, electronics manufacturers and electronic circuit design companies can efficiently select the optimal electronic components for a given circuit design to design electronic products more precisely as well as drastically reduce design time.

Furthermore, the present invention is not limited to the embodiments described above, and various modifications may be made without departing from the spirit of the present invention. Examples of such modifications include the following.
(1) The reference equivalent circuit presented in the embodiments described above is only an example, and the present invention can be applied to reference equivalent circuits of various configurations.
(2) The circuit constant values, ratios, and the like given in the embodiments above are similarly only examples and are not limited in any way.
(3) Although the description above focused primarily on applying the equivalent circuits illustrated in FIGS. 1A and 1B & FIGS. 2A and 2B that use the voltage-controlled current source E₁₀ to capacitive devices and resistive devices included in a reference equivalent circuit, the equivalent circuit illustrated in FIG. 3B that uses the voltage-controlled voltage source E₂₀ may be used instead. Moreover, although the embodiments above describe a case in which the reference equivalent circuit includes capacitive elements and resistive elements, this applies equally to inductive elements as well.
(4) Although above the present invention was applied to multilayer ceramic capacitors as a representative example, the present invention can also be applied to equivalent circuits for various types of capacitors.

### INDUSTRIAL APPLICABILITY

In the present invention, with respect to an equivalent circuit for when no DC voltage is applied, a circuit or circuits that represent changes in circuit characteristics due to superimposition of a DC voltage on a signal is added, thereby reducing computational load in simulations and also reducing the occurrence of computational problems due to divergence or the like. Moreover, the changes in the characteristics of the circuit elements when the DC voltage is superimposed can be expressed in a relatively simple and highly accurate manner, thereby making the present invention well-suited to analysis of the characteristics of multilayer ceramic capacitors and the like.

It will be apparent to those skilled in the art that various modifications and variations can be made in the present invention without departing from the spirit or scope of the invention. Thus, it is intended that the present invention cover modifications and variations that come within the scope of the appended claims and their equivalents. In particular, it is explicitly contemplated that any part or whole of any two or more of the embodiments and their modifications described above can be combined and regarded within the scope of the present invention.

What is claimed is:

1. A method of constructing an equivalent circuit for a capacitor to which a signal superimposed with a DC voltage may be applied, comprising:
defining a reference equivalent circuit that represents characteristics of said capacitor when the DC voltage is not applied and only the signal is applied;
determining a circuit value of each circuit element contained in the reference equivalent circuit by measuring responses of said capacitor when the DC voltage is not applied and only the signal is applied;
substituting a circuit element or a group of circuit elements that are included in the reference equivalent circuit and that have circuit values that change when the DC voltage is superimposed to the signal with a voltage-controlled current source or voltage-controlled voltage source; and
adding a closed circuit representing a state in which only the signal is applied to said voltage-controlled current source or voltage-controlled voltage source so that said voltage-controlled current source or voltage-controlled voltage source generates a current or voltage of a magnitude that is obtained by multiplying a current or voltage generated in the closed circuit by a coefficient.

2. The method of constructing the equivalent circuit for the capacitor according to claim 1, further comprising:
calculating a change in the circuit value of the circuit or the group of the circuit elements due to the superimposition of the DC voltage by comparing frequency characteristics of the circuit element or the group of circuit elements measured when the DC voltage is superimposed on the signal to frequency characteristics of the circuit elements or the group of circuit elements measured when only the signal is applied; and
determining said coefficient on the basis of the change in the value of the circuit element or the group of circuit elements due to superimposition of the DC voltage as obtained in the step of calculating.

3. The method of constructing the equivalent circuit for the capacitor according to claim 1,
wherein in the closed circuit, a voltage source or current source is connected in series to the circuit element or the group of circuit elements that have been substituted with the voltage-controlled current source or voltage-controlled voltage source, and
wherein an output of the voltage-controlled current source or voltage-controlled voltage source is controlled in accordance with a voltage or current applied by the voltage source or current source to the closed circuit.

4. The method of constructing the equivalent circuit for the capacitor according to claim 2,
wherein in the closed circuit, a voltage source or current source is connected in series to the circuit element or the group of circuit elements that have been substituted with the voltage-controlled current source or voltage-controlled voltage source, and
wherein an output of the voltage-controlled current source or voltage-controlled voltage source is controlled in accordance with a voltage or current applied by the voltage source or current source to the closed circuit.

5. The method of constructing the equivalent circuit for the capacitor according to claim 1, wherein the reference equivalent circuit includes a plurality of circuit elements that have same changes in response to the superimposition of the DC voltage, and a pair of said voltage-controlled current source or voltage-controlled voltage source and the associated closed circuit are provided for said plurality of circuit elements.

6. The method of constructing the equivalent circuit for the capacitor according to claim 2, wherein the reference equivalent circuit includes a plurality of circuit elements that have same changes in response to the superimposition of the DC voltage, and a pair of said voltage-controlled current source or voltage-controlled voltage source and the associated closed circuit are provided for said plurality of circuit elements.

7. The method of constructing the equivalent circuit for the capacitor according to claim 3, wherein the reference equivalent circuit includes a plurality of circuit elements that have same changes in response to the superimposition of the DC voltage, and a pair of said voltage-controlled current source or voltage-controlled voltage source and the associated closed circuit are provided for said plurality of circuit elements.

8. The method of constructing the equivalent circuit for the capacitor according to claim 4, wherein the reference equivalent circuit includes a plurality of circuit elements that have same changes in response to the superimposition of the DC voltage, and a pair of said voltage-controlled current source or voltage-controlled voltage source and the associated closed circuit are provided for said plurality of circuit elements.

9. The method of constructing the equivalent circuit for the capacitor according to claim 1, wherein the capacitor is a multilayer ceramic capacitor.

10. The method of constructing the equivalent circuit for the capacitor according to claim 2, wherein the capacitor is a multilayer ceramic capacitor.

11. The method of constructing the equivalent circuit for the capacitor according to claim 3, wherein the capacitor is a multilayer ceramic capacitor.

12. The method of constructing the equivalent circuit for the capacitor according to claim 4, wherein the capacitor is a multilayer ceramic capacitor.

13. The method of constructing the equivalent circuit for the capacitor according to claim 5, wherein the capacitor is a multilayer ceramic capacitor.

14. The method of constructing the equivalent circuit for the capacitor according to claim 6, wherein the capacitor is a multilayer ceramic capacitor.

15. The method of constructing the equivalent circuit for the capacitor according to claim 7, wherein the capacitor is a multilayer ceramic capacitor.

16. The method of constructing the equivalent circuit for the capacitor according to claim 8, wherein the capacitor is a multilayer ceramic capacitor.

17. A method of simulating characteristics of an electronic circuit that includes a capacitor, comprising:
substituting the capacitor in the electronic circuit with an equivalent circuit for the capacitor constructed by the method of constructing according to claim 1 so as to construct an equivalent circuit for the electronic circuit;
running a simulation program for the electronic circuit using the constructed equivalent circuit for the electronic circuit to output simulations results simulating the characteristics of the electronic circuit.

18. A method of simulating characteristics of an electronic circuit that includes a capacitor, comprising:
substituting the capacitor in the electronic circuit with an equivalent circuit for the capacitor constructed by the method of constructing according to claim 2 so as to construct an equivalent circuit for the electronic circuit;
running a simulation program for the electronic circuit using the constructed equivalent circuit for the electronic circuit to output simulations results simulating the characteristics of the electronic circuit.

19. A method of simulating characteristics of an electronic circuit that includes a capacitor, comprising:
substituting the capacitor in the electronic circuit with an equivalent circuit for the capacitor constructed by the method of constructing according to claim 3 so as to construct an equivalent circuit for the electronic circuit;
running a simulation program for the electronic circuit using the constructed equivalent circuit for the electronic circuit to output simulations results simulating the characteristics of the electronic circuit.

20. A simulation device for simulating characteristics of an electronic circuit that includes a capacitor, comprising:
a processor programmed to receive an equivalent circuit for the electronic circuit, the equivalent circuit for the electronic circuit being constructed by substituting the capacitor in the electronic circuit with an equivalent circuit for the capacitor constructed by the method of constructing according to claim 1, the processor running a simulation program for the electronic circuit using the constructed equivalent circuit for the electronic circuit and causing simulation results simulating the characteristics of the electronic circuit to be outputted.
